(19) United States
(12) Patent Application Publication
(10) Pub. No.: US 2026/0096213 A1
(43) Pub. Date: Apr. 2, 2026

(54) Thin Film Transistor Substrate and Display Device Using the Same

(71) Applicant: LG Display Co., Ltd., Seoul (KR)

(72) Inventors: HyunCheol Cho, Paju-si (KR); ChanYong Jeong, Paju-si (KR); DaeHwan Kim, Paju-si (KR)

(21) Appl. No.: 19/307,826

(22) Filed: Aug. 22, 2025

(30) Foreign Application Priority Data
Oct. 2, 2024 (KR) 10-2024-0133928

(51) Int. Cl. H10D 86/40; H10D 86/60; H10K 59/121

(52) U.S. Cl. CPC H10D 86/441; H10D 86/60; H10K 59/1213

(57) ABSTRACT

A thin film transistor substrate comprises a substrate, an active layer on the substrate, a gate electrode on the active layer, a first conductive layer and a second conductive layer disposed between the active layer and the gate electrode, a source electrode on the first conductive layer; and a drain electrode on the second conductive layer, wherein the first conductive layer is disposed on one side of the active layer and overlaps a portion of the gate electrode, wherein the second conductive layer is disposed on the other side of the active layer and overlaps another portion of the gate electrode, wherein the first conductive layer and second conductive layer are spaced apart from each other in a first direction within a portion overlapping the gate electrode, and wherein the first direction intersects a second direction in which the source electrode and the drain electrode face each other.

### CROSS-REFERENCE TO RELATED APPLICATION

This application claims the benefit of priority of the Republic of Korea Patent Application No. 10-2024-0133928 filed on October 2, 2024, which is hereby incorporated by reference in its entirety.

### BACKGROUND

### Field of Technology

The present disclosure relates to a thin film transistor substrate and a display device using the same.

### Discussion of the Related Art

As the information society continues to advance, the demand for display devices for presenting images is increasing in various forms. Accordingly, in recent years, various display devices such as Liquid Crystal Display (LCD), Plasma Display Panel (PDP), and Organic Light Emitting Display (OLED) have been employed.

Among these display devices, OLEDs are self-emissive and offer advantages such as a wider viewing angle and higher contrast ratio compared to LCDs. Because they do not require a separate backlight, they enable lightweight and slim form factors and are advantageous in terms of power consumption. In addition, OLEDs may be driven by direct current at low voltages, have fast response times, and are particularly cost-effective to manufacture.

Thin film transistors TFT may be classified based on the material used for their active layer: amorphous silicon TFT, polysilicon TFT, and oxide semiconductor TFT.

Among these, oxide semiconductor TFT offers high mobility and may exhibit large variations in resistance depending on the oxygen content, making it easy to achieve desired electrical property. Furthermore, during the manufacturing process of oxide semiconductor TFT, the oxide forming the active layer may be deposited at relatively low temperatures, which reduces production costs. Due to the nature of oxides, oxide semiconductors are transparent, making them suitable for implementing transparent display devices.

As the operation time of a thin-film transistor increases, heat generated in regions overlapping the gate electrode tends to accumulate and degrade the characteristics of the device. Accordingly, various attempts have been made to dissipate such heat. In addition, various approaches have been tried to improve the on-current characteristics of the device, but with conventional doping methods, it is difficult to precisely control the channel length.

### SUMMARY

As the driving time of a thin-film transistor TFT increases, heat generated in regions overlapping the gate electrode tends to accumulate and can degrade the characteristic of the device. Accordingly, various attempts have been made to dissipate such heat. Furthermore, many efforts have also been made to improve the on-current characteristic of the device. However, with conventional doping method, it is difficult to control the channel length as desired.

In order to achieve The object, a thin film transistor substrate including a substrate, an active layer on the substrate, a gate electrode on the active layer, a first conductive layer and a second conductive layer disposed between the active layer and the gate electrode, a source electrode on the first conductive layer, and a drain electrode on the second conductive layer, wherein the first conductive layer is disposed on one side of the active layer and overlaps with a portion of the gate electrode, the second conductive layer is disposed on the other side of the active layer and overlaps with another portion of the gate electrode, and the first conductive layer and the second conductive layer are spaced apart from each other along a first direction in a portion overlapping with the gate electrode, the first direction being perpendicular to a second direction in which the source electrode and the drain electrode face each other, and a display device including the same are provided.

Furthermore, the present disclosure provides a thin film transistor substrate including a substrate, an active layer on the substrate, a gate electrode on the active layer, a source electrode on one side of the active layer, a drain electrode disposed on the other side of the active layer, a first conductive layer disposed between one side of the active layer and the source electrode, and a second conductive layer disposed between the other side of the active layer and the drain electrode, wherein the first conductive layer comprises a first body part and a first protrusion provided to protrude from the first body part and overlap with a part of the gate electrode, and the second conductive layer comprises a second body part and a second protrusion provided to protrude from the second body part and overlap with another part of the gate electrode, and current is provided to flow in a first direction through the active layer disposed between the first protrusion and the second protrusion in an area overlapping with the gate electrode, the first direction being perpendicular to a direction in which the source electrode and the drain electrode face each other, and a display device including the same.

### BRIEF DESCRIPTION OF THE DRAWINGS

The and other objects, features and other advantages of the present disclosure will be more clearly understood from the following detailed description taken in conjunction with the accompanying drawings, in which:

FIG. 1 is a schematic perspective view of a display device according to one embodiment of the present disclosure.

FIG. 2 is a plan view schematically showing a display device according to one embodiment of the present disclosure.

FIG. 3 is a plan view of a thin film transistor substrate according to one embodiment of the present disclosure.

FIGS. 4A and 4B are schematic plan views of a thin film transistor substrate according to one embodiment of the present disclosure.

FIG. 5 is a cross-sectional view of a thin film transistor substrate according to one embodiment of the present disclosure. In this case, FIG. 5 is a cross-sectional view taken along line I-I' of FIG. 3.

FIG. 6 is a cross-sectional view of a thin film transistor substrate according to one embodiment of the present disclosure. In this case, FIG. 6 is a cross-sectional view taken along line II-II' of FIG. 3.

FIG. 7 is a cross-sectional view of a thin film transistor substrate according to one embodiment of the present disclosure. In this case, FIG. 7 is a cross-sectional view taken along line III-III' of FIG. 3.

FIG. 8 is a cross-sectional view of a thin film transistor substrate according to another embodiment of the present disclosure. In this case, FIG. 8 is a cross-sectional view taken along line I-I' of FIG. 3.

FIG. 9 is a cross-sectional view of a thin film transistor substrate according to another embodiment of the present disclosure. In this case, FIG. 9 is a cross-sectional view taken along line II-II' of FIG. 3.

FIG. 10 is a plan view of a thin film transistor substrate according to another embodiment of the present disclosure.

FIG. 11 is a cross-sectional view of a thin film transistor substrate according to another embodiment of the present disclosure. In this case, FIG. 11 is a cross-sectional view taken along line IV-IV' of FIG. 10.

FIG. 12 is a plan view of a thin film transistor substrate according to another embodiment of the present disclosure.

FIGS. 13A and 13B are schematic plan views of a thin film transistor substrate according to another embodiment of the present disclosure.

FIG. 14 is a cross-sectional view of a thin film transistor substrate according to another embodiment of the present disclosure. In this case, FIG. 14 is a cross-sectional view taken along line V-V' of FIG. 12.

FIG. 15 is a cross-sectional view of a display device including a thin film transistor substrate according to one embodiment of the present disclosure.

FIG. 16 is a circuit diagram of one pixel provided in a display device according to one embodiment of the present disclosure.

### DETAILED DESCRIPTION

The advantages and features of the present disclosure, and the methods for achieving them, will become clear with reference to the embodiments described in detail below together with the accompanying drawings. However, the present disclosure is not limited to the embodiments disclosed below, but may be implemented in various different forms, and these embodiments are disposed only to make the disclosure of the present disclosure complete and to fully inform a person having ordinary skill in the art to which the present disclosure belongs of the scope of the invention, and the present disclosure is defined only by the scope of the claims.

The shapes, sizes, ratios, angles, numbers, or the like disclosed in the drawings for explaining embodiments of the present disclosure are exemplary, and therefore the present disclosure is not limited to the matters illustrated. Like reference numerals refer to like elements throughout the specification. In addition, in describing the present disclosure, if it is determined that a detailed description of a related known technology may unnecessarily obscure the gist of the present disclosure, the detailed description will be omitted. When the terms “includes,” “has,” “consists of,” or the like are used in this specification, other parts may be added unless “only” is used. When a component is expressed in the singular, it includes a case where the plural is included unless there is a specifically explicit description.

When interpreting a component, it is interpreted as including the error range even if there is no separate explicit description.

When describing a positional relationship, for example, when the positional relationship between two parts is described as 'on ~', 'upper ~', 'lower ~', 'next to ~', or the like, one or more other parts may be located between the two parts, unless 'right' or 'directly' is used.

When describing a temporal relationship, for example, when describing a temporal relationship using phrases such as 'after', 'following', 'next to', or 'before', it may also include cases where there is no continuity, as long as 'right away' or 'directly' is not used.

Although the terms first, second, or the like are used to describe various components, these components are not limited by these terms. These terms are only used to distinguish one component from another. Accordingly, a first component referred to below may also be a second component within the technical concept of the present disclosure.

The individual features of the various embodiments of the present disclosure may be partially or wholly combined or combined with each other, and may be technically linked and driven in various ways, and each embodiment may be implemented independently of each other or may be implemented together in a related relationship.

Hereinafter, preferred embodiments of the present disclosure will be described in detail with reference to the drawings.

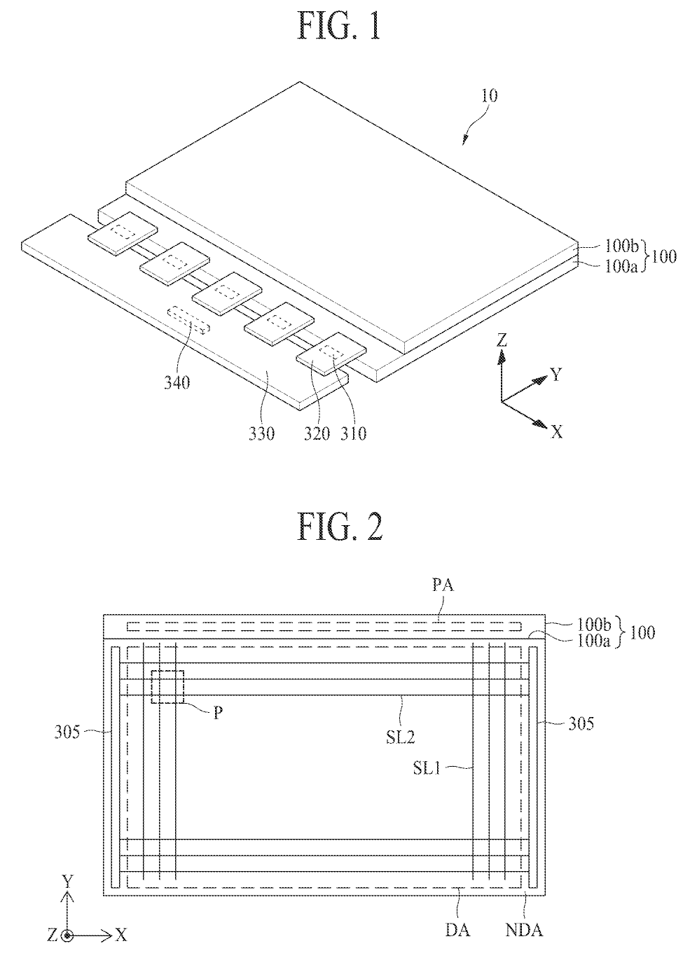

FIG. 1 is a schematic perspective view of a display device according to one embodiment of the present disclosure.

FIG. 2 is a plan view schematically showing a display device according to one embodiment of the present disclosure.

Hereinafter, the X-axis represents a direction parallel to the gate line, the Y-axis represents a direction parallel to the data line, and the Z-axis represents the height direction of the display device 10.

The display device 10 according to one embodiment of the present disclosure has been described mainly as being implemented as an organic light emitting display, but may also be implemented as a liquid crystal display, a plasma display panel (PDP), a quantum dot light emitting display (QLED), or an electrophoresis display.

Referring to FIG. 1 and FIG. 2, a display device 10 according to one embodiment of the present disclosure includes a display panel 100, a source drive integrated circuit (hereinafter referred to as “IC”) 310, a flexible film 320, a circuit board 330, and a timing control unit 340.

The display panel 100 includes the first substrate 100a and the second substrate 100b facing each other. The second substrate 100b may be a sealing substrate. The first substrate 100a may be a plastic film, a glass substrate, or a silicon wafer substrate formed using a semiconductor process. The second substrate 100b may be a plastic film, a glass substrate, or a sealing film. The first substrate 100a and the second substrate 100b may be made of a transparent material.

The display panel 100 may be divided into a display area DA where pixels are formed to display an image and a non-display area NDA where no image is displayed.

The display area DA may be provided with a plurality of vertical signal lines SL1, a plurality of horizontal signal lines SL2, and a plurality of pixels P, and the non-display area NDA may be provided with a pad area PA in which pads are arranged and at least one gate driver 305. Meanwhile, FIG. 2 illustrates a state in which one gate driver 305 is disposed on each of one side and the other side of the display panel 100, but is not limited thereto.

The plurality of vertical signal lines SL1 may extend in a second direction (Y-axis direction) and may intersect the plurality of horizontal signal lines SL2 in the display area DA. The plurality of vertical signal lines SL1 may be, for example, a high-potential voltage line supplying a high-potential voltage to an anode electrode, a reference voltage line transmitting a reference signal to each of the plurality of pixels P, a data line transmitting a data signal to each of the plurality of pixels P, or the like, but are not limited thereto, and according to the level of technology in the art, the plurality of vertical signal lines SL1 may be one of various wirings transmitting signals.

The plurality of horizontal signal lines SL2 may extend in a first direction (X-axis direction) in the display area DA. The plurality of horizontal signal lines SL2 may be, for example, gate lines that transmit gate signals to each of the plurality of pixels P, but are not limited thereto, and according to the level of technology in the art, the plurality of horizontal signal lines SL2 may be one of various wirings that transmit signals.

The plurality of pixels P are provided in an area where the plurality of first signal lines SL1 are provided or in an area where the plurality of first signal lines SL1 and the plurality of second signal lines SL2 intersect, and emit a predetermined amount of light to display an image.

The source drive IC 310 receives digital video data and a source control signal from the timing control unit 340. The source drive IC 310 converts digital video data into analog data voltages according to the source control signal and supplies the same to the data line. When the source drive IC 310 is manufactured as a driving chip, it may be mounted on the flexible film 320 in a COF (chip on film) or COP (chip on plastic) method.

Wires connecting the pads and the source drive IC 310, and wires connecting the pads and the wires of the circuit board 330 may be disposed on the flexible film 320. The flexible film 320 is attached onto the pads using an anisotropic conducting film, thereby connecting the pads and the wires of the flexible film 320.

The circuit board 330 may be attached to the flexible films 320. The circuit board 330 may have a plurality of circuits implemented with driving chips mounted thereon. For example, the timing control unit 340 may be mounted on the circuit board 330. The circuit board 330 may be a printed circuit board or a flexible printed circuit board.

The timing control unit 340 receives digital video data and a timing signal from an external system board (not shown). The timing control unit 340 generates a gate control signal for controlling the operation timing of the gate driver based on the timing signal and a source control signal for controlling the source drive ICs 310. The timing control unit 340 supplies the gate control signal to the gate driver 305 and the source control signal to the source drive ICs 310.

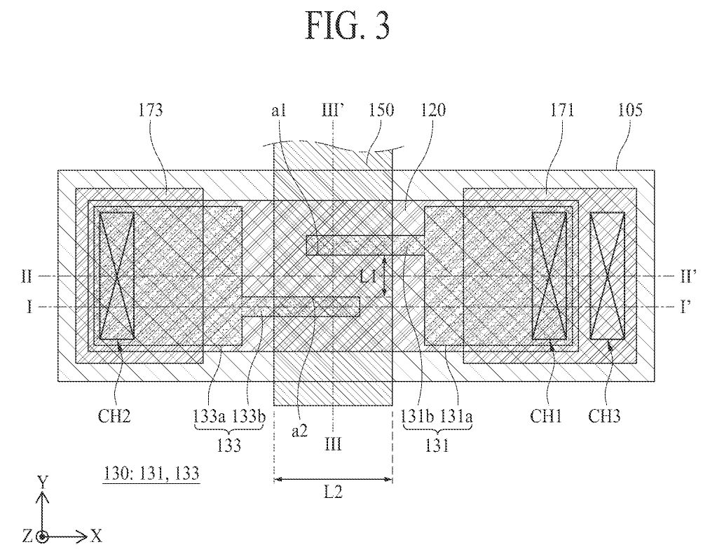

FIG. 3 is a plan view of a thin film transistor substrate according to one embodiment of the present disclosure.

As may be seen in FIG. 3, a thin film transistor substrate according to one embodiment of the present disclosure comprises a light shielding layer 105, an active layer 120, a conductive layer 130, a gate electrode 150, a source electrode 171, and a drain electrode 173.

The active layer 120 and the light shielding layer 105 may extend along a first direction X, for example, a horizontal direction. In this case, the first direction X may be, for example, a direction in which the source electrode 171 and the drain electrode 173 face each other. Meanwhile, the second direction Y may be a vertical direction, and the second direction Y may be, for example, a direction perpendicular to the first direction X.

The conductive layer 130 is provided to overlap with the active layer 120, and a portion of the conductive layer 130 may overlap with the gate electrode 150.

The conductive layer 130 is composed of a first conductive layer 131 that overlaps one side of the active layer 120, for example, the right side, and a second conductive layer 133 that overlaps the other side of the active layer 120, for example, the left side.

According to one embodiment of the present disclosure, the first conductive layer 131 and the second conductive layer 133 are provided to be spaced apart from each other along the second direction Y in an area overlapping the gate electrode 150.

The first conductive layer 131 is formed by overlapping one side of the active layer 120 and including a first body part 131a electrically connected to one side of the active layer 120 and a first protrusion 131b formed by protruding in the first direction X from the first body part 131a.

The first body part 131a does not overlap with the gate electrode 150.

The first protrusion 131b protrudes along the first direction X from one side of the first body part 131a, for example, the left side, and a part of the first protrusion 131b may overlap with the gate electrode 150.

The first protrusion 131b protrudes from the first body part 131a and extends along the first direction X to overlap the gate electrode 150, but may not cross the gate electrode 150. For example, the first protrusion 131b may overlap one side of the gate electrode 150, for example, the right side, but may not overlap the other side of the gate electrode 150, for example, the left side.

The length of the first protrusion 131b in the second direction Y may be shorter than the length of the first body part 131a in the second direction Y.

The second conductive layer 133 is formed by overlapping the other side of the active layer 120 and including a second body part 133a electrically connected to the other side of the active layer 120 and a second protrusion 133b formed by protruding from the second body part 133a in the first direction X.

The second body part 133a does not overlap with the gate electrode 150.

The second protrusion 133b protrudes along the first direction X from one side of the second body part 133a, for example, the right side, and a part of the second protrusion 133b may overlap with the gate electrode 150.

The second protrusion 133b protrudes from the second body part 133a and extends along the first direction X to overlap the gate electrode 150, but may not cross the gate electrode 150. For example, the second protrusion 133b may overlap the other side of the gate electrode 150, for example, the left side, but may not overlap one side of the gate electrode 150, for example, the right side.

The length of the second protrusion 133b in the second direction Y may be shorter than the length of the second body part 133a in the second direction Y.

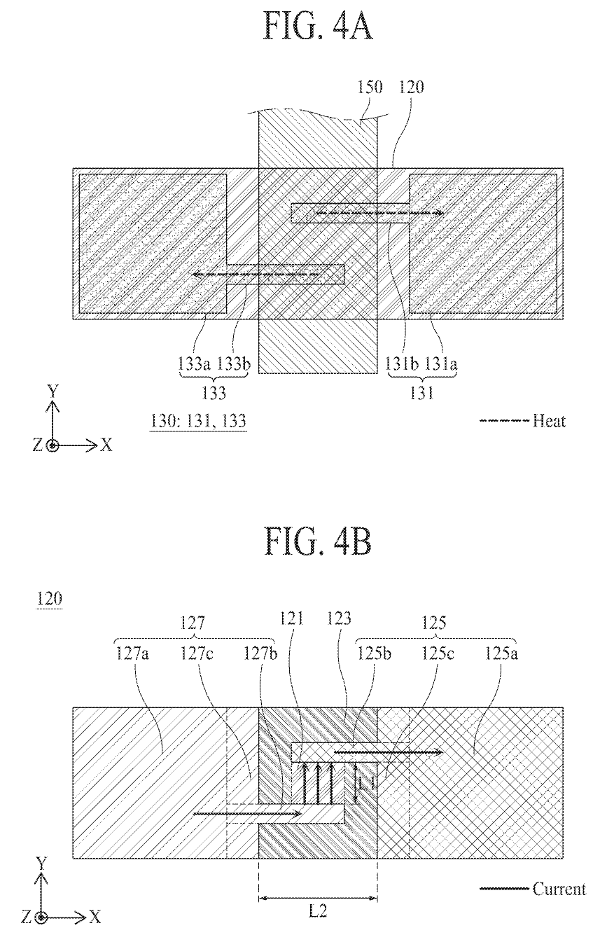

According to one embodiment of the present disclosure, the first protrusion 131b and the second protrusion 133b may be provided to face each other in an area overlapping the gate electrode 150. For example, one side a1 of the first protrusion 131b, for example, the lower side, may be provided to face one side a2 of the second protrusion 133b, for example, the upper side. In this case, the first length L1 between the one side a1 of the first protrusion 131b and the one side a2 of the second protrusion 133b may be provided to be shorter than the second length L2 of the gate electrode 150 in the first direction X. By being formed in this method, the thin film transistor substrate according to one embodiment of the present disclosure may secure improved on-current characteristic, which will be described in more detail with reference to FIG. 4B.

The gate electrode 150 may extend in a second direction Y, for example, a vertical direction. The gate electrode 150 may overlap a portion of the active layer 120.

The source electrode 171 may be disposed on one side of the active layer 120, for example, on the right side. The source electrode 171 may be electrically connected to one side of the active layer 120 through the first contact hole CH1.

The drain electrode 173 may be disposed on the other side of the active layer 120, for example, on the left side. The drain electrode 173 may be electrically connected to the other side of the active layer 120 through the second contact hole CH2.

The light shielding layer 105 may extend in the first direction X, for example, in the horizontal direction. The light shielding layer 105 may overlap with the active layer 120 to prevent light coming in from the outside from reaching the active layer 120.

The mentioned light shielding layer 105 may be electrically connected to the source electrode 171 through the third contact hole CH3.

FIG. 4A and FIG. 4B are schematic plan views of a thin film transistor substrate according to one embodiment of the present disclosure. FIG. 4A is a plan view briefly illustrating the configuration of an active layer, a conductive layer, and a gate electrode in order to show a path along which heat moves in an area overlapping a gate electrode of a thin film transistor substrate according to the embodiment of FIG. 3, and FIG. 4B is a plan view briefly illustrating the configuration of an active layer in order to show a portion where a channel is formed of a thin film transistor substrate according to the embodiment of FIG. 3.

First, as may be seen in FIG. 4A, according to one embodiment of the present disclosure, the first protrusion 131b of the first conductive layer 131 and the second protrusion 133b of the second conductive layer 133 are formed to partially overlap with the gate electrode 150, so that when the thin film transistor substrate according to one embodiment of the present disclosure is turned on, heat generated in the channel formed in the area overlapping with the gate electrode 150 may be easily dispersed through the first conductive layer 131 and the second conductive layer 133. Therefore, the thin film transistor substrate according to one embodiment of the present disclosure may be prevented from being overheated and the characteristic of the device from being deteriorated.

In detail, when the thin film transistor substrate according to one embodiment of the present disclosure is driven, a channel is disposed on the active layer 120 in an area overlapping the gate electrode 150. In this case, as the driving of the thin film transistor substrate continues, excessive heat may be generated in the channel formed in the active layer 120, that is, in an area overlapping the gate electrode 150. According to one embodiment of the present disclosure, since the first protrusion 131b is formed in the area overlapping the gate electrode 150, heat generated in the area overlapping the gate electrode 150 may move along the first protrusion 131b and the first body part 131a and thus be dispersed. Similarly, since the second protrusion 133b is formed in the area overlapping with the gate electrode 150, heat generated in the area overlapping with the gate electrode 150 may be dispersed as it moves along the second protrusion 133b and the second body part 133a.

Next, as may be seen in FIG. 4B, the active layer 120 of the thin film transistor substrate according to one embodiment of the present disclosure may include a channel part 121, a sub-channel part 123, a first conductive portion 125, and a second conductive portion 127.

The channel part 121 and the sub-channel part 123 are provided to overlap with the gate electrode 150 and may not overlap with the conductive layer 130. By being formed in this manner, the channel part 121 and the sub-channel part 123 may maintain semiconductor characteristic.

The channel part 121 may be disposed between the first protrusion 131b of the first conductive layer 131 and the second protrusion 133b of the second conductive layer 133 in an area overlapping the gate electrode 150. The channel part 121 may be disposed between the first protrusion 131b and the second protrusion 133b, and thus may have a first length L1 in the second direction Y. The channel part 121 may be a portion in which charges are accumulated to form a channel when a voltage higher than a threshold voltage Vth is applied to the gate electrode 150, and in which current actually flows. In this case, the direction in which current flows in the channel part 121 may be the second direction Y, for example, in a vertical direction, but is not limited thereto. The direction in which current flows in the channel part 121 may be perpendicular to the first direction X, which is the direction in which the active layer 120 extends, but is not limited thereto.

The sub-channel part 123 may be defined as a portion that overlaps with the gate electrode 150, a portion that does not overlap with the first protrusion 131b and the second protrusion 133b, and a remaining portion excluding the channel part 121. A portion between one side of the sub-channel part 123, for example, the left side, and the other side of the sub-channel part 123, for example, the right side, may have the second length L2 the same as the gate electrode 150. The sub-channel part 123 may maintain semiconductor characteristic, and may be a portion in which charges are accumulated to form a channel when a voltage higher than a threshold voltage Vth is applied to the gate electrode 150, but in which current does not actually flow.

According to one embodiment of the present disclosure, the second length L2 in the first direction X between one side, for example, the left side, and the other side, for example, the right side, of the sub-channel part 123 may be provided to be longer than the first length L1 between one side, for example, the upper side, and the other side, for example, the lower side, of the channel part 121. By forming in this method, even if a voltage higher than the threshold voltage Vth is applied to the gate electrode 150 and an electric field is applied to the source electrode 171 and the drain electrode 173, current may not flow through the sub-channel part 123 but may flow only through the channel part 121.

According to one embodiment of the present disclosure, by forming the channel part 121 shorter than the length of the first direction X of the gate electrode 150, the length of the channel of the thin film transistor is formed short, and a short channel may be implemented, and accordingly, a thin film transistor substrate having improved on-current characteristic may be implemented.

The first conductive portion 125 includes a first connecting portion 125a, a first intermediate part 125b, and a first diffusion portion 125c. In this case, the first connecting portion 125a to the first diffusion portion 125c may be portions having conductive property by being provided in contact with or adjacent to the first conductive layer 131.

For example, the first connecting portion 125a and the first intermediate part 125b overlap with the first conductive layer 131, and thus may have conductive characteristic by the first conductive layer 131. For example, the first diffusion portion 125c does not overlap with the first conductive layer 131, but is provided adjacent to the first conductive layer 131, and thus may be provided with conductive characteristic when the first conductive layer 131 is formed. The first conductive portion 125 has relatively higher conductive characteristic than the channel part 121 and the sub-channel part 123, and may be used as a wiring or a source/drain electrode.

In detail, the first conductive portion 125 may be provided with conductive property by oxygen vacancy formed when oxygen present in a portion of the active layer 120 is absorbed into the first conductive layer 131 when the first conductive layer 131 and the active layer 120 come into contact.

The first connecting portion 125a may overlap with the first body part 131a of the first conductive layer 131. The first connecting portion 125a may be disposed on one side of the active layer 120, for example, on the right side.

The first intermediate part 125b may overlap with the first protrusion 131b of the first conductive layer 131. Accordingly, the first intermediate part 125b may be formed in a shape that protrudes from the first connecting portion 125a along the first direction X.

The first intermediate part 125b may be provided to protrude from the first connecting portion 125a and be adjacent to the channel part 121 and the sub-channel part 123. For example, a portion of the first intermediate part 125b may be provided to be surrounded by the channel part 121 and the sub-channel part 123. For example, a portion of one side of the first intermediate part 125b, for example, the lower side, may be provided to be in contact with the channel part 121, and another portion of the first intermediate part 125b may be in contact with the sub-channel part 123.

Meanwhile, the first intermediate part 125b is provided to be in contact with the first protrusion 131b of the first conductive layer 131, but since the area of the first protrusion 131b is relatively small compared to the area of the first body part 131a, the amount of oxygen absorbed by the first protrusion 131b in the area adjacent to the first intermediate part 125b may be relatively small or non-existent.

Accordingly, unlike the first diffusion portion 125c being formed in the area adjacent to the first connecting portion 125a, a separately conductorized area may not be formed in the area adjacent to the first intermediate part 125b. As a result, it is possible to implement the length of the channel part 121 formed between the first intermediate part 125b and the second intermediate part 127b to be the same as the design.

The first diffusion portion 125c may not overlap with the first conductive layer 131. The first diffusion portion 125c may be conductorized together with the first connecting portion 125a in the process of being conductorized by the first body part 131a of the first conductive layer 131. For example, the first body part 131a may have a relatively large area compared to the first protrusion 131b. Accordingly, when the first body part 131a absorbs oxygen present in a portion of the active layer 120, an oxygen vacancy may be formed in the first connecting portion 125a and, at the same time, an oxygen vacancy may be formed in the first diffusion portion 125c provided adjacent to the first connecting portion 125a. Accordingly, a conductive property may be imparted to the first diffusion portion 125c.

The first diffusion portion 125c may be disposed so as not to overlap with the gate electrode 150, but is not limited thereto.

The second conductive portion 127 includes a second connecting portion 127a, a second intermediate part 127b, and a second diffusion portion 127c. In this case, the second connecting portion 127a to the second diffusion portion 127c may be portions having conductive property by being provided in contact with or adjacent to the second conductive layer 133.

For example, the second connecting portion 127a and the second intermediate part 127b overlap with the second conductive layer 133, and thus may have conductive characteristic by the second conductive layer 133. For example, the second diffusion portion 127c does not overlap with the second conductive layer 133, but is provided adjacent to the second conductive layer 133, and thus may be provided with conductive characteristic when the second conductive layer 133 is formed. The second conductive portion 127 has relatively higher conductive characteristic than the channel part 121 and the sub-channel part 123, and may be used as a wiring or a source/drain electrode.

In detail, the second conductive portion 127 may be provided with conductive property by oxygen vacancy formed when oxygen present in another part of the active layer 120 is absorbed into the second conductive layer 133 when the second conductive layer 133 and the active layer 120 come into contact.

The second connecting portion 127a may overlap with the second body part 133a of the second conductive layer 133. The second connecting portion 127a may be disposed on the other side of the active layer 120, for example, on the left side.

The second intermediate part 127b may overlap with the second protrusion 133b of the second conductive layer 133. Accordingly, the second intermediate part 127b may be formed in a shape that protrudes from the second connecting portion 127a along the first direction X.

The second intermediate part 127b may be provided to protrude from the second connecting portion 127a and be adjacent to the channel part 121 and the sub-channel part 123. For example, a portion of the second intermediate part 127b may be provided to be surrounded by the channel part 121 and the sub-channel part 123. For example, a portion of one side of the second intermediate part 127b, for example, the upper side, may be provided to be in contact with the channel part 121, and another portion of the second intermediate part 127b may be in contact with the sub-channel part 123.

Meanwhile, the second intermediate part 127b is disposed to be in contact with the second protrusion 133b of the second conductive layer 133, but since the area of the second protrusion 133b is relatively small compared to the area of the second body part 133a, the amount of oxygen absorbed by the second protrusion 133b in the area adjacent to the second intermediate part 127b may be relatively small or non-existent.

Accordingly, unlike the second diffusion portion 127c being formed in the area adjacent to the second connecting portion 127a, a separately conductorized area may not be formed in the area adjacent to the second intermediate part 127b. As a result, it is possible to implement the length of the channel part 121 formed between the second intermediate part 127b and the first intermediate part 125b to be the same as the design.

The second diffusion portion 127c may not overlap with the second conductive portion 133. The second diffusion portion 127c may be conductorized together with the second connecting portion 127a in the process of being conductorized by the second body part 133a of the second conductive layer 133. For example, the second body part 133a may have a relatively large area compared to the second protrusion 133b. Accordingly, while the second body part 133a absorbs oxygen present in another part of the active layer 120, it may form an oxygen vacancy in the second connecting portion 127a and at the same time, form an oxygen vacancy in the second diffusion portion 127c adjacent to the second connecting portion 127a. Accordingly, a conductive characteristic may be imparted to the second diffusion portion 127c.

The second diffusion portion 127c may be provided so as not to overlap with the gate electrode 150, but is not limited thereto.

According to one embodiment of the present disclosure, the first intermediate part 125b of the first conductive portion 125 and the second intermediate part 127b of the second conductive portion 127 may be provided to face each other. For example, one side of the first intermediate part 125b, for example, the lower side, and one side of the second intermediate part 127b, for example, the upper side, may be provided to face each other, so that the area where the first intermediate part 125b and the second intermediate part 127b face each other may be defined as the channel part 121, and current may flow along the channel part 121. As described above, since the first length L1 in the second direction Y between the first intermediate part 125b and the second intermediate part 127b is formed shorter than the second length L2, a channel shorter than the length of the gate electrode 150 in the first direction X may be implemented, thereby implementing improved on-current characteristic.

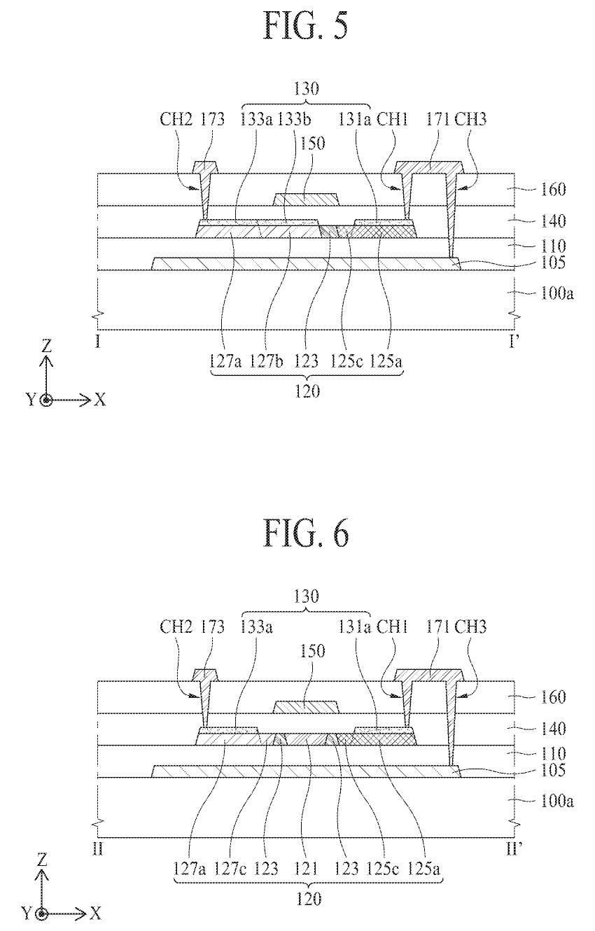

FIG. 5 is a cross-sectional view of a thin film transistor substrate according to one embodiment of the present disclosure. In this case, FIG. 5 is a cross-sectional view taken along line I-I' of FIG. 3.

As may be seen in FIG. 5, a thin film transistor substrate according to one embodiment of the present disclosure comprises a first substrate 100a, a light shielding layer 105, a buffer layer 110, an active layer 120, a conductive layer 130, a gate insulating layer 140, a gate electrode 150, an interlayer insulating layer 160, a source electrode 171, and a drain electrode 173.

The first substrate 100a may be made of glass or plastic. In particular, the first substrate 100a may be made of a transparent plastic having flexible property, for example, polyimide. When polyimide is used as the first substrate 100a, considering that a high-temperature deposition process is predisposed on the first substrate 100a, a heat-resistant polyimide that may withstand high temperatures may be used.

The light shielding layer 105 may be disposed on the first substrate 100a. The mentioned light shielding layer 105 may be formed of a metal or a metal oxide, and may be formed of one metal layer or metal oxide layer, or may be formed of two or more metal layers or metal oxide layers.

The light shielding layer 105 is disposed below the active layer 120 and overlaps with the active layer 120, thereby preventing light from the outside of the thin film transistor substrate from entering the active layer 120. In detail, the light shielding layer 105 may prevent external light from entering the channel part 121 of the active layer 120. Meanwhile, although not shown, a separate lower buffer layer may be added between the light shielding layer 105 and the first substrate 100a to block air and moisture from entering from the outside of the first substrate 100a.

The buffer layer 110 is disposed on the first substrate 100a and the light shielding layer 105. The buffer layer 110 may protect the active layer 120 by blocking air and moisture. The buffer layer 110 may be formed of an inorganic insulating material such as silicon oxide, silicon nitride, or metal oxide, but is not necessarily limited thereto and may be formed of an organic insulating material. The buffer layer 110 may be formed of a single layer or may be formed of a plurality of layers.

The active layer 120 may be disposed on the buffer layer 110.

The active layer 120 may be formed of a semiconductor material, for example, an oxide semiconductor material. The oxide semiconductor material may include, for example, at least one of an IZO (InZnO) based oxide semiconductor material, an IGO (InGaO) based oxide semiconductor material, an ITO (InSnO) based oxide semiconductor material, an IGZO (InGaZnO) based oxide semiconductor material, an IGZTO (InGaZnSnO) based oxide semiconductor material, a GZTO (GaZnSnO) based oxide semiconductor material, a GZO (GaZnO) based oxide semiconductor material, an ITZO (InSnZnO) based oxide semiconductor material, and a FIZO (FeInZnO) based oxide semiconductor material.

The active layer 120 is composed of a sub-channel part 123, a first conductive portion 125, and a second conductive portion 127.

The sub-channel part 123 may be a portion that is not in contact with the conductive layer 130 and thus is not given conductive characteristic. Since The sub-channel part 123 maintains semiconductor characteristic, when a voltage higher than the threshold voltage Vth is applied to the gate electrode 150, charges are accumulated and conductive characteristic may be selectively obtained.

The sub-channel part 123 may be provided to overlap with a portion of the gate electrode 150.

The first conductive portion 125 may be disposed on one side of the sub-channel part 123, for example, on the right side. The first conductive portion 125 may have conductive property by the conductive layer 130. Alternatively, a portion of the first conductive portion 125 may have conductive property through a conductorized process using the gate electrode 150 as a mask.

The first conductive portion 125 may include a first connecting portion 125a and a first diffusion portion 125c. The first connecting portion 125a may be a portion that comes into contact with the first body part 131a of the first conductive layer 131 and has conductive property. Since the first connecting portion 125a has relatively high conductive property compared to the sub-channel part 123, it may be used as a wiring or source/drain electrode.

The first diffusion portion 125c may be disposed between the sub-channel part 123 and the first connecting portion 125a. The first diffusion portion 125c may have conductive property while the first connecting portion 125a has conductive property due to the first body part 131a of the first conductive layer 131. In this case, the first diffusion portion 125c may have relatively high conductive property compared to the sub-channel part 123, and thus may be used as a wiring or a source/drain electrode. Meanwhile, the present disclosure is not limited thereto, and the first diffusion portion 125c may be provided with conductive property by performing a conductive process using the gate electrode 150 as a mask.

The conductorized process may be defined as a process of imparting conductive property to an oxide semiconductor material. An oxide semiconductor material that has undergone the conductorized process may have conductive property. The conductorized process may include, for example, a doping process using dopant ions and a plasma process that applies plasma to make it conductorized. Through the conductorized process, a portion of the active layer 120, for example, the first diffusion portion 125c of the first conductive portion 125, may be conductorized and have conductive property.

The second conductive portion 127 may be disposed on the other side of the sub-channel part 123, for example, on the left side. The second conductive portion 127 may have conductive property due to the conductive layer 130.

The second conductive portion 127 may include a second connecting portion 127a that is in contact with the second body part 133a of the second conductive layer 133 and has conductive characteristic, and a second intermediate part 127b that is in contact with the second protrusion 133b of the second conductive layer 133 and has conductive characteristic. The second connecting portion 127a and the second intermediate part 127b have conductive characteristic due to the second conductive layer 133, and thus have relatively high conductive characteristic compared to the sub-channel part 123, and thus may be used as wiring or source/drain electrodes.

The second intermediate part 127b may overlap with a portion of the gate electrode 150 and may be disposed on one side of the sub-channel part 123, for example, on the left side.

The conductive layer 130 may be disposed on the active layer 120. For example, the conductive layer 130 may be provided to contact a portion of the upper surface of the active layer 120 to impart conductive property to a portion of the active layer 120.

The conductive layer 130 may include a first conductive layer 131 disposed on one side of the active layer 120, for example, on the right side, and a second conductive layer 133 disposed on the other side of the active layer 120, for example, on the left side. Meanwhile, in the cross-sectional view of FIG. 5, the first conductive layer 131 and the second conductive layer 133 are only shown as being formed asymmetrically with respect to the gate electrode 150, but are not limited thereto.

For example, the first conductive layer 131 may be in contact with one upper surface of the active layer 120 and not overlap with the gate electrode 150, while the second conductive layer 133 may be in contact with the other upper surface of the active layer 120 and overlap with the gate electrode 150.

In detail, the second conductive layer 133 includes the second body part 133a disposed on the other side of the active layer 120 and the second protrusion 133b provided to protrude from the second body part 133a along the first direction X and overlap with a portion of the gate electrode 150.

According to one embodiment of the present disclosure, since the second protrusion 133b is provided to overlap the gate electrode 150, heat generated in the central portion of the active layer 120 by the voltage applied to the gate electrode 150 may easily move along the second protrusion 133b so that the heat may be quickly dispersed without accumulating in the central portion of the active layer 120. Accordingly, even when the thin film transistor according to one embodiment of the present disclosure is continuously driven, it is possible to prevent the element from being deteriorated by heat, and to minimize or eliminate changes in the characteristic of the element due to heat. Meanwhile, in FIG. 5, only the second protrusion 133b is shown overlapping with the gate electrode 150, but it is not limited thereto, and since the first protrusion (133a of FIG. 3) disposed on the second conductive layer 133 overlaps with the gate electrode 150, heat at the center of the active layer 120 may be easily dispersed.

The conductive layer 130 may be formed by including any one of metal materials. For example, the conductive layer 130 may be formed by including any one of copper (Cu), molybdenum (Mo), titanium (Ti), and aluminum (Al), but is not limited thereto and may be formed by including various metal materials known in the art.

The gate insulating layer 140 may be disposed on the active layer 120. In detail, the gate insulating layer 140 may be disposed on the entire surface of the first substrate 100a and may be disposed on the active layer 120 and the buffer layer 110. As a result, the active layer 120 may be disposed in a form in which it is wrapped by the buffer layer 110 and the gate insulating layer 140.

The gate insulating layer 140 may include, but is not limited to, a silicon nitride film (SiNx) or a silicon oxide film (SiOx). The gate insulating layer 140 may be formed of a single layer or multiple layers including an inorganic insulator and/or an organic insulator. Meanwhile, although not illustrated, the gate insulating layer 140 is not limited to being disposed on the entire surface of the first substrate 100a, and may be pattern-formed to match one end and the other end of the gate electrode 150.

The gate electrode 150 may be disposed on the gate insulating layer 140. The gate electrode 150 may be disposed on the active layer 120 and the conductive layer 130. The gate electrode 150 may overlap, for example, the sub-channel part 123 of the active layer 120, the second middle portion 127b of the second conductive portion 127, and the second protrusion 133b of the second conductive layer 133.

The gate electrode 150 may include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). The gate electrode 150 may have a structure including one metal layer or a multilayer structure including at least two metal layers each having different physical property.

The interlayer insulating layer 160 insulates between the gate electrode 150 and the source electrode 171, and further insulates between the gate electrode 150 and the drain electrode 173. The interlayer insulating layer 160 may be formed of a single layer or multiple layers including an inorganic insulating material and/or an organic insulating material.

The interlayer insulating layer 160 may be provided with a first contact hole CH1, a second contact hole CH2, and a third contact hole CH3. Accordingly, a part of the upper surface of the first conductive layer 131 disposed on one side of the active layer 120 may be exposed by the first contact hole CH1, and further, a part of the upper surface of the second conductive layer 133 disposed on the other side of the active layer 120 may be exposed by the second contact hole CH2. In detail, a part of the upper surface of the first body part 131a may be exposed by the first contact hole CH1, and a part of the upper surface of the second body part 133a may be exposed by the second contact hole CH2. Furthermore, a part of the upper surface of the light shielding layer 105 may be exposed by the third contact hole CH3.

The source electrode 171 and the drain electrode 173 may be disposed on the interlayer insulating layer 160. The source electrode 171 and the drain electrode 173 may be formed of the same material as the gate electrode 150, but are not limited thereto and may be formed of a material according to knowledge in the art. The source electrode 171 may be electrically connected to the first conductive layer 131 through the first contact hole CH1, the drain electrode 173 may be electrically connected to the second conductive layer 133 through the second contact hole CH2, and the source electrode 171 may be electrically connected to the light shielding layer 105 through the third contact hole CH3.

FIG. 6 is a cross-sectional view of a thin film transistor substrate according to one embodiment of the present disclosure. In this case, FIG. 6 is a cross-sectional view taken along line II-II' of FIG. 3. Meanwhile, the embodiment of FIG. 6 is identical to the embodiment of FIG. 5 except for the configuration of the active layer and the conductive layer, so the following description will focus on the different configuration.

As may be seen in FIG. 6, a thin film transistor substrate according to one embodiment of the present disclosure comprises a first substrate 100a, a light shielding layer 105, a buffer layer 110, an active layer 120, a conductive layer 130, a gate insulating layer 140, a gate electrode 150, an interlayer insulating layer 160, a source electrode 171, and a drain electrode 173.

The active layer 120 is composed of a channel part 121, a sub-channel part 123, a first conductive portion 125, and a second conductive portion 127.

The channel part 121 may be provided to overlap with the gate electrode 150, and may be a portion that is not provided with conductive property because it does not come into contact with the conductive layer 130. Since the channel part 121 maintains semiconductor property, when a voltage higher than the threshold voltage Vth is applied to the gate electrode 150, charges may be accumulated and the charges may move to cause current to flow. Meanwhile, although not specifically illustrated, charges in the channel part 121 move along the second direction Y and do not move along the sub-channel part 123.

The sub-channel part 123 may be disposed on one side and the other side of the channel part 121, for example, on the left and right sides. The sub-channel part 123 may overlap with the gate electrode 150.

The first conductive portion 125 may include the first connecting portion 125a and the first diffusion portion 125c. The first connecting portion 125a may be disposed on one side of the active layer 120, for example, on the left side, and the first diffusion portion 125c may be formed between the sub-channel part 123 and the first connecting portion 125a.

The second conductive portion 127 may be formed by including the second connecting portion 127a and the second diffusion portion 127c. The second connecting portion 127a may be disposed on the other side of the active layer 120, for example, on the right side, and the second diffusion portion 127c may be formed between the sub-channel part 123 and the second connecting portion 127a.

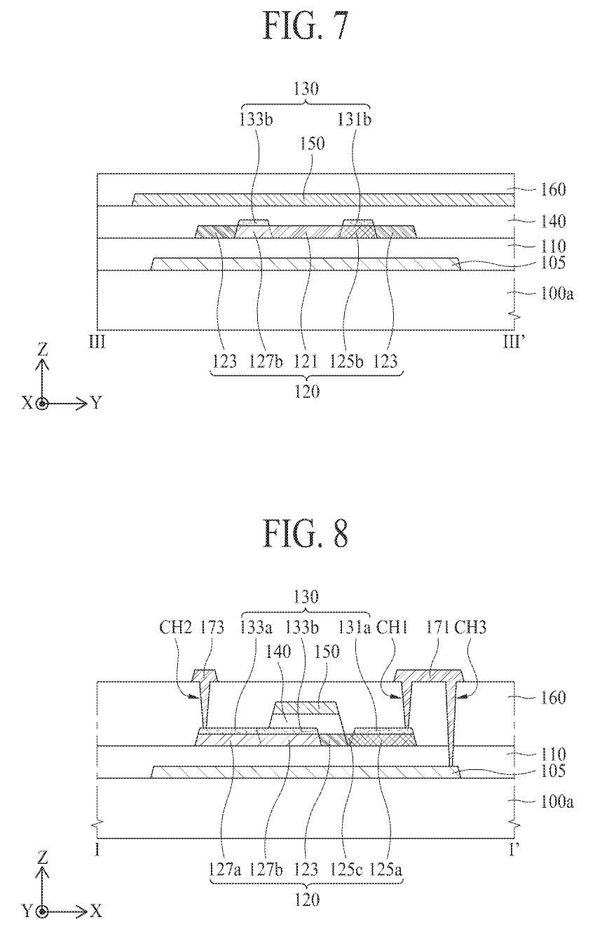

FIG. 7 is a cross-sectional view of a thin film transistor substrate according to one embodiment of the present disclosure. In this case, FIG. 7 is a cross-sectional view taken along line III-III' of FIG. 3. Meanwhile, the embodiment of FIG. 7 relates to the same embodiment as the embodiments of FIGS. 5 and 6, and the same components are given the same drawing reference numerals, and repeated descriptions are omitted.

As may be seen in FIG. 7, a thin film transistor substrate according to one embodiment of the present disclosure comprises a first substrate 100a, a light shielding layer 105, a buffer layer 110, an active layer 120, a conductive layer 130, a gate insulating layer 140, a gate electrode 150, and an interlayer insulating layer 160.

According to one embodiment of the present disclosure, the channel part 121 of the active layer 120 overlaps the gate electrode 150 and may be disposed between the second intermediate part 127b of the second conductive portion 127 having conductive property by contacting the second protrusion 133b of the second conductive layer 133 and the first intermediate part 125b of the first conductive portion 125 having conductive property by contacting the first protrusion 131b of the first conductive layer 131. By forming in this method, when a voltage higher than the threshold voltage Vth is applied to the gate electrode 150 and an electric field is applied to the source electrode (see 171 of FIG. 5) and the drain electrode (see 173 of FIG. 5), current moves along the channel part 121 in the second direction Y.

FIG. 8 is a cross-sectional view of a thin film transistor substrate according to another embodiment of the present disclosure. In this case, FIG. 8 is a cross-sectional view taken along line I-I' of FIG. 3. Meanwhile, the embodiment of FIG. 8 is the same as the embodiment of FIG. 5 except for the configuration of the gate insulating layer, so the following description will focus on the different configuration.

As may be seen from FIG. 8, a thin film transistor substrate according to another embodiment of the present disclosure comprises a gate insulating layer 140 patterned to correspond to one end and the other end of the gate electrode 150. In detail, one end and the other end of the gate insulating layer 140, for example, a left end and a right end, respectively, may be provided to correspond to one end and the other end of the gate electrode 150, for example, a left end and a right end.

By being formed in this method, a part of the upper surface of the first conductive layer 131 may be in contact with the interlayer insulating layer 160, and a part of the upper surface of the second conductive layer 133 may be in contact with the interlayer insulating layer 160. For example, the first body part 131a of the first conductive layer 131 does not overlap with the gate insulating layer 140, the second body part 133a of the second conductive layer 133 does not overlap with the gate insulating layer 140, and a part of the second protrusion 133b of the second conductive layer 133 may overlap with the gate insulating layer 140.

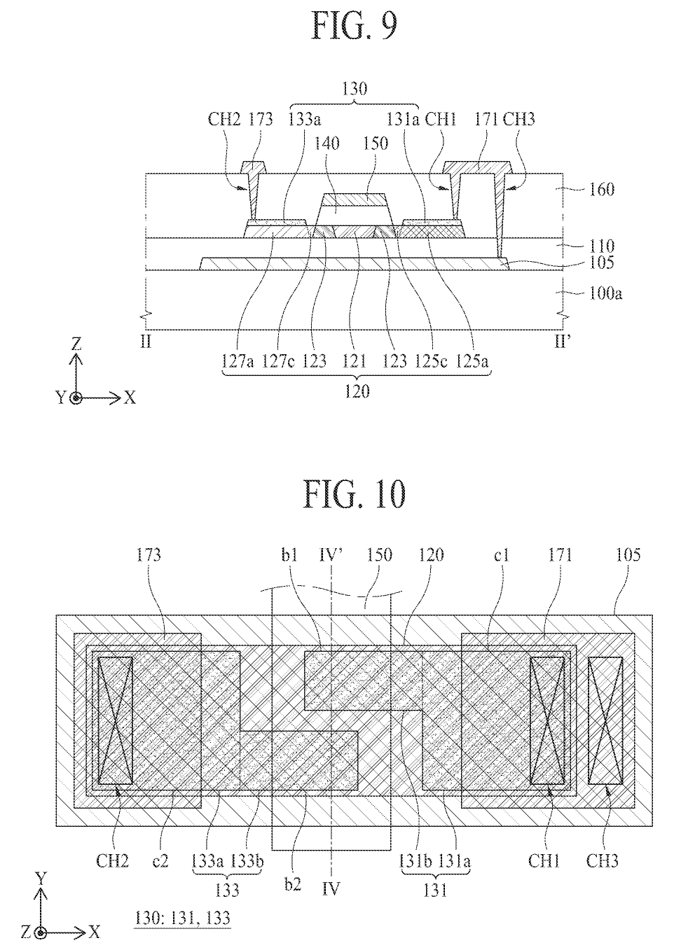

FIG. 9 is a cross-sectional view of a thin film transistor substrate according to another embodiment of the present disclosure. In this case, FIG. 9 is a cross-sectional view taken along line II-II' of FIG. 3. Meanwhile, the embodiment of FIG. 9 is the same as the embodiment of FIG. 6 except for the configuration of the gate insulating layer, so the following description will focus on the different configuration.

As may be seen in FIG. 9, a thin film transistor substrate according to another embodiment of the present disclosure comprises a gate insulating layer 140 patterned to correspond to one end and the other end of the gate electrode 150. In detail, one end and the other end of the gate insulating layer 140, for example, a left end and a right end, respectively, may be provided to correspond to one end and the other end of the gate electrode 150, for example, a left end and a right end.

The first diffusion portion 125c of the first conductive portion 125 may be exposed to the outside without being covered by the gate insulating layer 140, and the second diffusion portion 127c of the second conductive portion 127 may be exposed to the outside without being covered by the gate insulating layer 140. Meanwhile, the first diffusion portion 125c and the second diffusion portion 127c may be provided with conductive property during the process of pattern forming the gate insulating layer 140, but are not limited thereto.

FIG. 10 is a plan view of a thin film transistor substrate according to another embodiment of the present disclosure. Meanwhile, the embodiment of FIG. 10 is identical to the embodiment of FIG. 3 except for the configuration of the protrusion of the conductive layer, so the following description will focus on the different configuration.

As may be seen in FIG. 10, a thin film transistor substrate according to another embodiment of the present disclosure comprises a light shielding layer 105, an active layer 120, a conductive layer 130, a gate electrode 150, a source electrode 171, and a drain electrode 173.

According to another embodiment of the present disclosure, unlike the embodiment of FIG. 3, the first protrusion 131b of the first conductive layer 131 and the second protrusion 133b of the second conductive layer 133 may be formed to extend in the second direction Y. In detail, the first protrusion 131b of the first conductive layer 131 may extend in the second direction Y to correspond to one side of the active layer 120, for example, the upper side, and the second protrusion 133b of the second conductive layer 133 may extend in the second direction Y to correspond to the other side of the active layer 120, for example, the lower side.

Alternatively, the first side b1 of the first protrusion 131b, for example, the upper side, may correspond to the first side c1 of the first body part 131a, for example, the upper side. In other words, the extension line of the first side c1 of the first body part 131a and the extension line of the first side b1 of the first protrusion 131b may coincide with each other. Similarly, the first side b2 of the second protrusion 133b, for example, the lower side, may correspond to the first side c2 of the second body part 133a, for example, the lower side. In other words, the extension line of the first side c2 of the second body part 133a and the extension line of the first side b2 of the second protrusion 133b may coincide with each other. Meanwhile, the present disclosure is not limited thereto.

By being formed in this manner, the area overlapping the gate electrode 150 and/or the area overlapping the active layer 120 of each of the first protrusion 131b and the second protrusion 133b increases, so that heat generated in the area overlapping the gate electrode 150 may move and be dispersed more quickly along the first conductive layer 131 and the second conductive layer 133. As a result, it is possible to prevent the thin film transistor substrate according to another embodiment of the present disclosure from deteriorating and changing the characteristic of the device.

Meanwhile, although not specifically illustrated, by the first protrusion 131b and the second protrusion 133b, one side, for example, the upper side, of the first intermediate part (see 125b of FIG. 4B) of the active layer 120 corresponds to one side, for example, the upper side, of the first connecting portion (see 125a of FIG. 4B) of the active layer 120, and the other side facing the one side of the first intermediate part (see 125b of FIG. 4B) may come into contact with the channel part (see 121 of FIG. 4B). Likewise, one side of the second intermediate part (see 127b of FIG. 4B) of the active layer 120, for example, the lower side, corresponds to one side of the second connecting portion (see 127a of FIG. 4B) of the active layer 120, for example, the upper side, and the other side facing the one side of the second intermediate part (see 127b of FIG. 4B) may be in contact with the channel part (see 121 of FIG. 4B).

FIG. 11 is a cross-sectional view of a thin film transistor substrate according to another embodiment of the present disclosure. In this case, FIG. 11 is a cross-sectional view taken along line IV-IV' of FIG. 10. Meanwhile, the embodiment of FIG. 11 is related to the same embodiment as the embodiment of FIG. 10, and the same components are given the same drawing reference numerals, and repeated descriptions are omitted.

As may be seen in FIG. 11, a thin film transistor substrate according to one embodiment of the present disclosure comprises a first substrate 100a, a light shielding layer 105, a buffer layer 110, an active layer 120, a conductive layer 130, a gate insulating layer 140, a gate electrode 150, and an interlayer insulating layer 160.

According to another embodiment of the present disclosure, the channel part 121 of the active layer 120 overlaps the gate electrode 150 and may be disposed between the second intermediate part 127b of the second conductive portion 127 having conductive property by contacting the second protrusion 133b of the second conductive layer 133 and the first intermediate part 125b of the first conductive portion 125 having conductive property by contacting the first protrusion 131b of the first conductive layer 131. By forming in this method, when a voltage higher than the threshold voltage Vth is applied to the gate electrode 150 and an electric field is applied to the source electrode (see 171 of FIG. 10) and the drain electrode (see 173 of FIG. 10), current moves along the channel part 121 in the second direction Y.

The first protrusion 131b of the first conductive layer 131 may be provided to correspond to one end of the active layer 120, for example, the right end, and the second protrusion 133b of the second conductive layer 133 may be provided to correspond to the other end of the active layer 120, for example, the left end. In this way, by forming the lengths of the first protrusion 131b and the second protrusion 133b in the second direction Y long, generated by the gate electrode 150 in the central portion of the active layer 120 may be quickly dispersed through the first protrusion 131b and the second protrusion 133b.

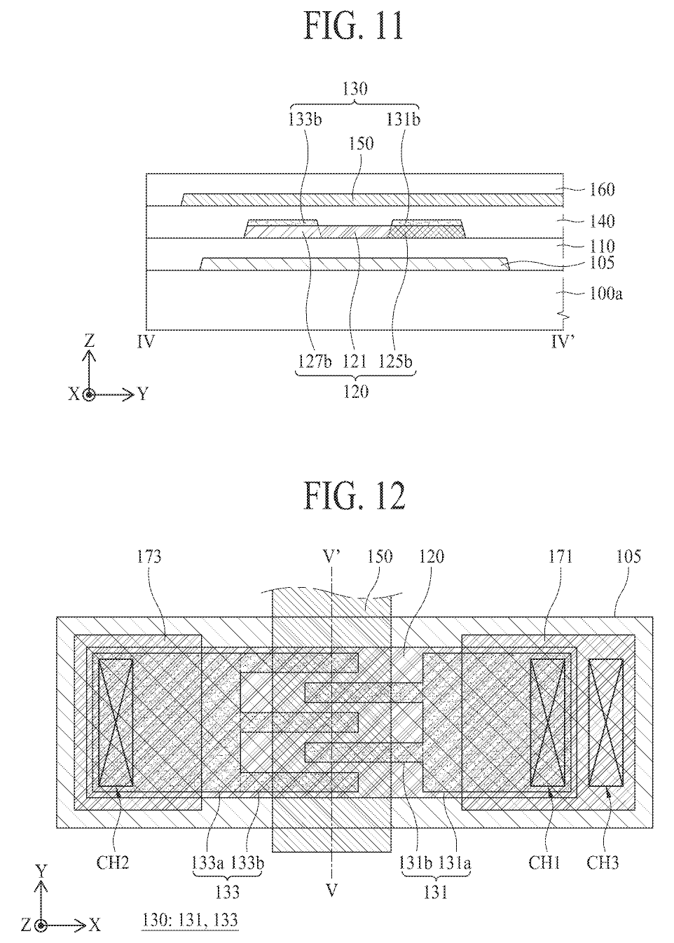

FIG. 12 is a plan view of a thin film transistor substrate according to another embodiment of the present disclosure. Meanwhile, the embodiment of FIG. 12 is identical to the embodiment of FIG. 3 except for the configuration of the conductive layer, so the following description will focus on the different configuration.

As may be seen in FIG. 12, a thin film transistor substrate according to another embodiment of the present disclosure comprises a light shielding layer 105, an active layer 120, a conductive layer 130, a gate electrode 150, a source electrode 171, and a drain electrode 173.

The conductive layer 130 is composed of a first conductive layer 131 that overlaps one side of the active layer 120, for example, the right side, and a second conductive layer 133 that overlaps the other side of the active layer 120, for example, the left side.

According to another embodiment of the present disclosure, the first conductive layer 131 includes the first body part 131a and a plurality of first protrusions 131b that protrude and extend from the first body part 131a, and the second conductive layer 133 includes the second body part 133a and a plurality of second protrusions 133b that protrude and extend from the second body part 133a.

The plurality of first protrusions 131b and the plurality of second protrusions 133b may be disposed to be spaced apart from each other, and may be arranged to alternately correspond to each other along the second direction Y. For example, the plurality of first protrusions 131b and the plurality of second protrusions 133b may be arranged to alternately correspond to each other in the direction in which the gate electrode 150 extends. One second protrusion 133b of the plurality of second protrusions 133b may be disposed between two adjacent first protrusions 131b of the plurality of first protrusions 131b.

According to another embodiment of the present disclosure, by including the plurality of first protrusions 131b and the plurality of second protrusions 133b, heat generated in an area overlapping the gate electrode 150 may be quickly spread and removed along the plurality of first protrusions 131b and the plurality of second protrusions 133b. Accordingly, it is possible to prevent the thin film transistor substrate from deteriorating, and ultimately, it is possible to prevent the characteristic of the device from changing.

Furthermore, according to another embodiment of the present disclosure, the number of the plurality of second protrusions 133b of the second conductive layer 133 electrically connected to the drain electrode 173 may be provided in a number different from the number of the plurality of first protrusions 131b of the first conductive layer 131 electrically connected to the source electrode 171, and for example, the number of the plurality of second protrusions 133b may be greater than the number of the plurality of first protrusions 131b. When the thin film transistor substrate is turned on, more heat is generated in an area relatively adjacent to the drain electrode 173 in the center area of the gate electrode 150 or the active layer 120. Since the number of the plurality of second protrusions 133b is provided to be greater than the number of the plurality of first protrusions 131b, heat concentrated in an area relatively adjacent to the drain electrode 173 in an area overlapping the gate electrode 150 may be more effectively dispersed.

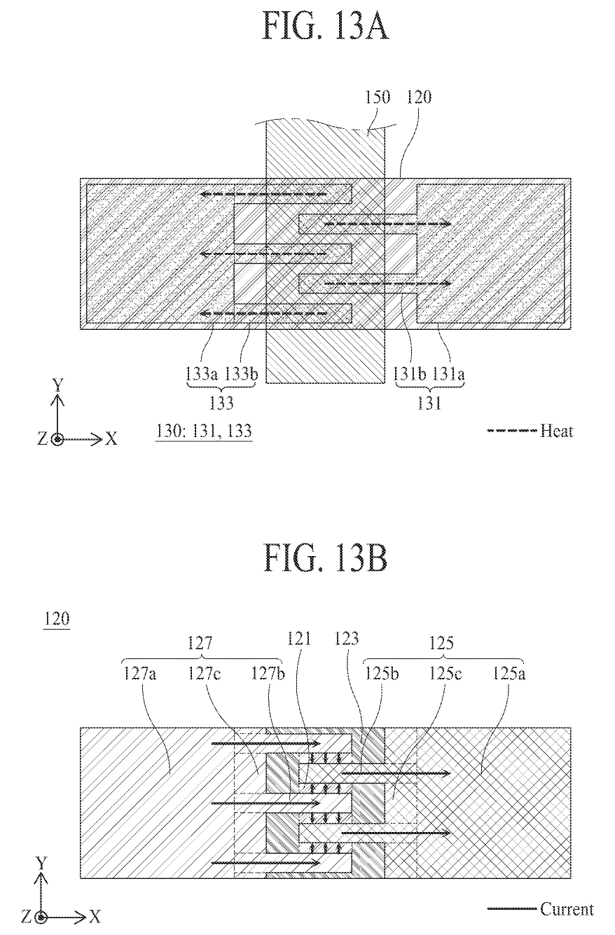

FIG. 13A and FIG. 13B are schematic plan views of a thin film transistor substrate according to another embodiment of the present disclosure. FIG. 13A is a plan view briefly illustrating the configuration of an active layer, a conductive layer, and a gate electrode in order to show a path along which heat moves in an area overlapping a gate electrode of the thin film transistor substrate in the embodiment of FIG. 12, and FIG. 13B is a plan view briefly illustrating the configuration of an active layer in order to show a portion where a channel of the thin film transistor substrate is formed in the embodiment of FIG. 12.

First, as may be seen in FIG. 13A, according to another embodiment of the present disclosure, the plurality of first protrusions 131b of the first conductive layer 131 and the second protrusions 133b of the plurality of second conductive layers 133 are formed to partially overlap with the gate electrode 150, so that when the thin film transistor substrate according to one embodiment of the present disclosure is turned on, heat generated in the channel formed in the area overlapping with the gate electrode 150 may be easily dispersed through the first conductive layer 131 and the second conductive layer 133. Therefore, the thin film transistor substrate according to one embodiment of the present disclosure may be prevented from being overheated and the characteristic of the device deteriorating.

In detail, when the thin film transistor substrate according to one embodiment of the present disclosure is driven, a channel is disposed on the active layer 120 in an area overlapping the gate electrode 150. In this case, as the driving of the thin film transistor substrate continues, excessive heat may be generated in the channel formed in the active layer 120, that is, in an area overlapping the gate electrode 150. According to another embodiment of the present disclosure, since the plurality of first protrusions 131b are formed in the area overlapping the gate electrode 150, heat generated in the area overlapping the gate electrode 150 may move along the plurality of first protrusions 131b and the first body part 131a and thus be dispersed. Likewise, since the plurality of second protrusions 133b are formed in the area overlapping with the gate electrode 150, heat generated in the area overlapping with the gate electrode 150 may be dispersed as it moves along the plurality of second protrusions 133b and the second body part 133a.

Next, as may be seen in FIG. 13B, the active layer 120 of the thin film transistor substrate according to another embodiment of the present disclosure may include a plurality of channel parts 121, sub-channel part 123, first conductive portion 125, and second conductive portion 127. Meanwhile, the embodiment of FIG. 13B is identical to the description of FIG. 4B except for the channel parts, the first connecting portion, and the second intermediate part, so a repeated description will be omitted.

According to another embodiment of the present disclosure, each of the plurality of channel parts 121 may be spaced apart from each other along the second direction Y, which is the direction in which the gate electrode 150 extends. Each of the plurality of channel parts 121 may be disposed between the plurality of first protrusions 131b and the plurality of second protrusions 133b.

The first conductive portion 125 is composed of a first connecting portion 125a, a plurality of first intermediate parts 125b, and a first diffusion portion 125c.

The plurality of first intermediate parts 125b may overlap with the plurality of first protrusions 131b of the first conductive layer 131. Accordingly, the plurality of first intermediate parts 125b may be formed in a shape that protrudes from the first connecting portion 125a along the first direction X.

The plurality of first intermediate parts 125b may be provided to protrude from the first connecting portion 125a and be adjacent to the plurality of channel parts 121 and the sub-channel part 123.

The second conductive portion 127 is composed of a second connecting portion 127a, a plurality of second intermediate parts 127b, and a second diffusion portion 127c.

The plurality of second intermediate parts 127b may overlap with the plurality of second protrusions 133b of the second conductive layer 133. Accordingly, the plurality of second intermediate parts 127b may be formed in a shape that protrudes from the second connecting portion 127a along the first direction X.

The plurality of second intermediate parts 127b may be provided to protrude from the second connecting portion 127a and be adjacent to the plurality of channel parts 121 and the sub-channel parts 123.

According to another embodiment of the present disclosure, when the thin film transistor substrate according to another embodiment of the present disclosure is turned on, current may flow from any one of the second protrusion 133b among the plurality of second protrusions 133b to the two first protrusions 131b that are adjacent to the selected second protrusion 133b. However, the present disclosure is not limited thereto.

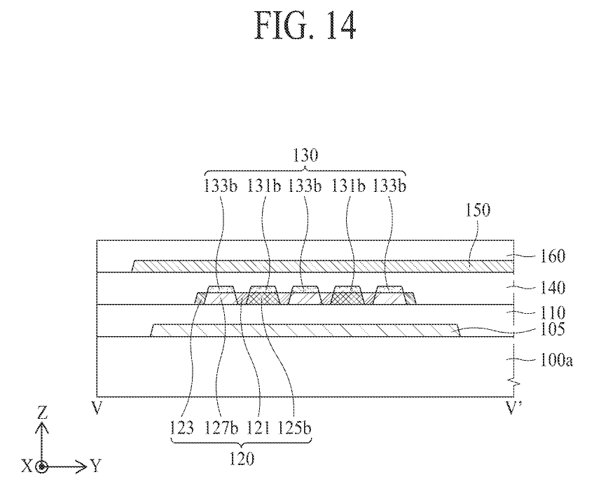

FIG. 14 is a cross-sectional view of a thin film transistor substrate according to another embodiment of the present disclosure. In this case, FIG. 14 is a cross-sectional view taken along line V-V' of FIG. 12. Meanwhile, the embodiment of FIG. 14 is related to the same embodiment as the embodiment of FIG. 12, and the same components are given the same drawing reference numerals, and repeated descriptions are omitted.

As may be seen in FIG. 14, a thin film transistor substrate according to one embodiment of the present disclosure comprises a first substrate 100a, a light shielding layer 105, a buffer layer 110, an active layer 120, a conductive layer 130, a gate insulating layer 140, a gate electrode 150, and an interlayer insulating layer 160.

According to another embodiment of the present disclosure, the plurality of channel parts 121 of the active layer 120 may overlap the gate electrode 150 and be disposed between the plurality of second intermediate parts 127b of the second conductive portion 127, which are in contact with the second protrusions 133b of the second conductive layer 133, and the plurality of first intermediate parts 125b of the first conductive portion 125, which are in contact with the first protrusions 131b of the first conductive layer 131. By forming in this method, when a voltage higher than the threshold voltage Vth is applied to the gate electrode 150 and an electric field is applied to the source electrode (see 171 of FIG. 10) and the drain electrode (see 173 of FIG. 10), current moves along the second direction Y along the plurality of channel parts 121. In this case, current may flow in different directions in channel parts provided adjacently among the plurality of channel parts 121.

For example, the plurality of first intermediate parts 125b and the plurality of second intermediate parts 127b may be alternately disposed along the second direction Y, and one of the plurality of channel parts 121 may be formed between one of the plurality of first intermediate parts 125b and one of the plurality of second intermediate parts 127b. In this case, current may flow from one of the plurality of second intermediate parts 127b to one of the plurality of first intermediate parts 125b adjacent to one of the plurality of second intermediate parts 127b.

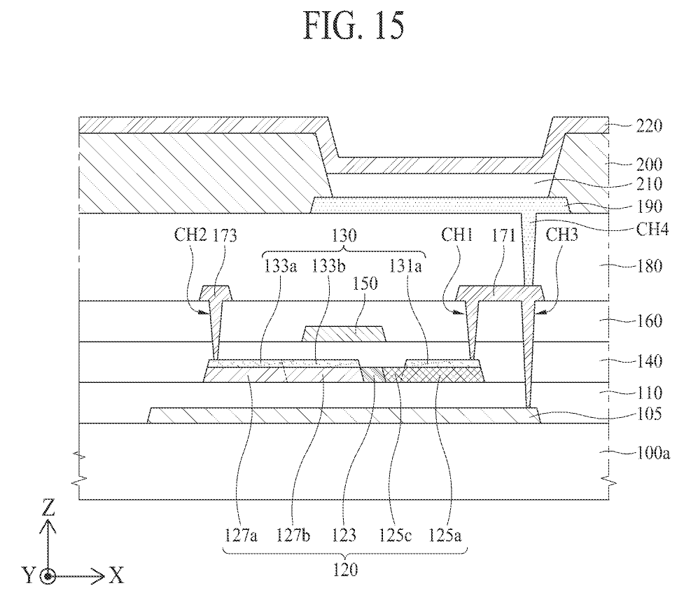

FIG. 15 is a cross-sectional view of a display device including a thin film transistor substrate according to one embodiment of the present disclosure.

As may be seen in FIG. 15, a display device according to one embodiment of the present disclosure includes a first substrate 100a, a light shielding layer 105, a buffer layer 110, an active layer 120, a conductive layer 130, a gate insulating layer 140, a gate electrode 150, an interlayer insulating layer 160, a source electrode 171, a drain electrode 173, a flattening layer 180, a first electrode 190, a bank layer 200, a light emitting layer 210, and a second electrode 220.

Meanwhile, the first substrate 100a, the light shielding layer 105, the buffer layer 110, the active layer 120, the conductive layer 130, the gate insulating layer 140, the gate electrode 150, the interlayer insulating layer 160, the source electrode 171, and the drain electrode 173 are the same as those in the described embodiments, so a repeated description will be omitted.

The flattening layer 180 may be disposed on the source electrode 171 and the drain electrode 173.

The flattening layer 180 is provided with a fourth contact hole CH4, so that a portion of the upper surface of the source electrode 171 may be exposed by the fourth contact hole CH4. However, depending on the case, a portion of the upper surface of the drain electrode 173 may be exposed by the fourth contact hole CH4.

The first electrode 190 is disposed on the flattening layer 180 and is connected to the source electrode 171 or the drain electrode 173 through the fourth contact hole CH4. The first electrode 190 may function as an anode.

The bank layer 200 is provided to cover the edge of the first electrode 190 and defines a light emitting area. Accordingly, the upper surface area of the first electrode 190 that is exposed and not covered by the bank layer 200 becomes a light emitting area.

The light emitting layer 210 is disposed on the first electrode 190. The light emitting layer 210 may be formed by including red, green, and blue light emitting layers patterned for each pixel, or may be formed by a white light emitting layer connected to all pixels. When the light emitting layer 210 is formed by a white light emitting layer, the light emitting layer 210 may be formed by including, for example, a first stack including a blue light emitting layer, for example, a second stack including a yellow-green light emitting layer, and a charge generation layer disposed between the first stack and the second stack, but is not necessarily limited thereto.

The second electrode 220 is disposed on the light emitting layer 210. The second electrode 220 may function as a cathode.

Although not shown, a sealing layer may be additionally disposed on the second electrode 220 to prevent the penetration of moisture or oxygen.

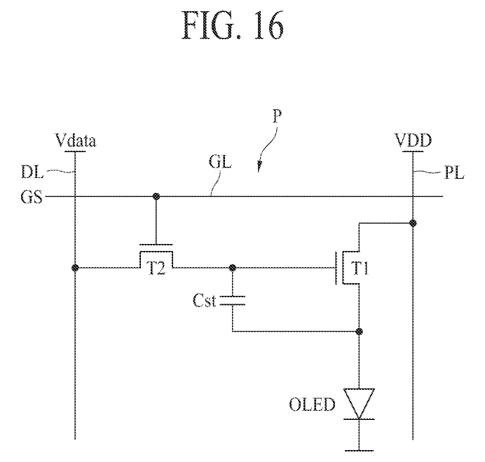

FIG. 16 is a circuit diagram of one pixel provided in a display device according to one embodiment of the present disclosure.

As may be seen in FIG. 16, a display device according to one embodiment of the present disclosure includes first and second thin film transistors T1, T2 and a capacitor Cst.

The first thin film transistor T1 is a driving thin film transistor, and the second thin film transistor T2 is a switching thin film transistor. At least one of the first thin film transistor T1 and the second thin film transistor T2 may be formed of various thin film transistors as described above.

The first thin film transistor T1 is switched according to the data voltage Vdata supplied from the second thin film transistor T2 to generate a data current from the driving voltage VDD supplied from the power line PL and supply it to the organic light emitting diode OLED.

The second thin film transistor T2 is switched according to a gate signal GS supplied to the gate line GL and supplies a data voltage Vdata supplied from a data line DL to the first thin film transistor T1.

The capacitor Cst serves to maintain the data voltage supplied to the first thin film transistor T1 for one frame, and is disposed between the gate electrode and the source electrode of the first thin film transistor T1.

The organic light emitting diode OLED emits a predetermined amount of light according to the data current supplied from the first thin film transistor T1.

Although the embodiments of the present disclosure have been described in more detail with reference to the attached drawings, the present disclosure is not necessarily limited to these embodiments, and various modifications may be made without departing from the technical idea of the present disclosure. Accordingly, the embodiments disclosed in the present disclosure are not intended to limit the technical idea of the present disclosure, but to explain it, and the scope of the technical idea of the present disclosure is not limited by these embodiments. Therefore, it should be understood that the embodiments described above are exemplary in all aspects and not restrictive. The protection scope of the present disclosure should be interpreted by the claims, and all technical ideas within a scope equivalent thereto should be interpreted as being included in the scope of the rights of the present disclosure.

According to the present disclosure as described above, the following effects are achieved.

According to one embodiment of the present disclosure, by rapidly dispersing and moving heat generated in an area overlapping the gate electrode by the first conductive layer and the second conductive layer which are disposed on one side and the other side of the active layer and are arranged to overlap the gate electrode, the characteristic of the device may be prevented from deteriorating. This may further ensure the reliability of the device.

According to one embodiment of the present disclosure, a thin film transistor substrate having a short channel may be implemented by providing a first conductive layer and a second conductive layer so that the first conductive layer and the second conductive layer are shorter than the widthwise length of the gate electrode in a portion overlapping the gate electrode. Accordingly, a thin film transistor substrate having improved on-current characteristic may be implemented by forming a channel having a short length.

The effects of the present disclosure are not limited to the effects mentioned above, and other effects not mentioned will be clearly understood by those skilled in the art from the description below.

What is claimed is:

1. A thin film transistor substrate comprising:
a substrate;
an active layer on the substrate;
a gate electrode on the active layer;
a first conductive layer and a second conductive layer disposed between the active layer and the gate electrode;
a source electrode on the first conductive layer; and
a drain electrode on the second conductive layer,
wherein the first conductive layer is disposed on one side of the active layer and overlaps a portion of the gate electrode,
wherein the second conductive layer is disposed on another side of the active layer and overlaps another portion of the gate electrode,
wherein the first conductive layer and second conductive layer are spaced apart from each other in a first direction within a portion overlapping the gate electrode, and
wherein the first direction intersects a second direction in which the source electrode and the drain electrode face each other.

2. The thin film transistor substrate of claim 1,
wherein the first conductive layer and second conductive layer are spaced apart from each other in the first direction by a first length within the portion overlapping the gate electrode, and
wherein the first length is smaller than a second length of the gate electrode in the second direction.

3. The thin film transistor substrate of claim 1,
wherein the first conductive layer comprises a first body part disposed on one side of the active layer and a first protrusion protruding from the first body part and overlapping a portion of the gate electrode,
wherein the second conductive layer comprises a second body part disposed on the another side of the active layer and a second protrusion protruding from the second body part and overlapping another portion of the gate electrode, and
wherein the first protrusion and second protrusion are spaced apart from each other in the first direction within the portion overlapping the gate electrode.

4. The thin film transistor substrate of claim 3,
wherein the first protrusion overlaps one side of the gate electrode and does not overlap another side of the gate electrode, and
wherein the second protrusion overlaps the another side of the gate electrode and does not overlap the one side of the gate electrode.

5. The thin film transistor substrate of claim 3,
wherein one side surface of the first protrusion and one side surface of the second protrusion face each other.

6. The thin film transistor substrate of claim 3,
wherein a distance in the first direction between one side surface of the first protrusion and one side surface of the second protrusion is less than a distance in the second direction between one side and the another side of the gate electrode.

7. The thin film transistor substrate of claim 1,
wherein the first conductive layer comprises a first body part disposed on one side of the active layer and a plurality of first protrusions protruding from the first body part and overlapping a portion of the gate electrode,
wherein the second conductive layer comprises a second body part that does not overlap the gate electrode and a plurality of second protrusions protruding from the second body part and overlapping another portion of the gate electrode, and
wherein the plurality of first protrusions and the plurality of second protrusions are spaced apart from each other in the first direction within the portion overlapping the gate electrode.

8. The thin film transistor substrate of claim 7,
wherein the plurality of first protrusions and the plurality of second protrusions are alternately disposed along a direction in which the gate electrode extends.

9. The thin film transistor substrate of claim 7,
wherein the plurality of first protrusions comprises a 1-1. protrusion and a 1-1. protrusion spaced apart from each other within the portion overlapping the gate electrode,
wherein the plurality of second protrusions comprises a 2-1. protrusion, and
wherein the 2-1. protrusion is disposed between the 2-1. protrusion and the 2-1. protrusion.

10. The thin film transistor substrate of claim 7,
wherein the number of the plurality of first protrusions is less than the number of the plurality of second protrusions.

11. The thin film transistor substrate of claim 3,
wherein the active layer comprises a channel part, a first connecting portion overlapping the first body part, a first intermediate part overlapping the first protrusion, a second connecting portion overlapping the second body part, and a second intermediate part overlapping the second protrusion, and
wherein the channel part is disposed between the first intermediate part and the second intermediate part.

12. The thin film transistor substrate of claim 11,
wherein a length of the channel part in the first direction is shorter than a length of the gate electrode in the second direction.

13. The thin film transistor substrate of claim 7,
wherein the active layer comprises a channel part, a first connecting portion overlapping the first body part, a plurality of first intermediate parts overlapping the plurality of first protrusions, a second connecting portion overlapping the second body part, and a plurality of second intermediate parts overlapping the plurality of second protrusions, and
wherein the channel part is disposed between one of the plurality of first intermediate parts and one of the plurality of second intermediate parts.

14. The thin film transistor substrate of claim 13,
wherein the channel part comprises a plurality of channel parts,
wherein each of the plurality of channel parts is disposed between one of the plurality of first intermediate parts and one of the plurality of second intermediate parts, and
wherein the plurality of channel parts are disposed along a direction in which the gate electrode extends.

15. A thin film transistor substrate comprising:
a substrate;
an active layer on the substrate;
a gate electrode on the active layer;
a source electrode on one side of the active layer;
a drain electrode on another side of the active layer;
a first conductive layer disposed between the one side of the active layer and the source electrode; and
a second conductive layer disposed between the another side of the active layer and the drain electrode,
wherein the first conductive layer comprises a first body part and a first protrusion protruding from the first body part and overlapping a portion of the gate electrode,
wherein the second conductive layer comprises a second body part and a second protrusion protruding from the second body part and overlapping another portion of the gate electrode,
wherein current flows in a first direction through the active layer disposed between the first protrusion and second protrusion in a portion overlapping the gate electrode, and
wherein the first direction intersects a direction in which the source and drain electrodes face each other.

16. The thin film transistor substrate of claim 15,
wherein a length in the first direction between the first protrusion and second protrusion is less than a length in the second direction of the gate electrode,
wherein the second direction is a direction in which the source and drain electrodes face each other.

17. The thin film transistor substrate of claim 15,
wherein the first protrusion comprises a plurality of first protrusions,
wherein the second protrusion comprises a plurality of second protrusions, and
wherein the plurality of first protrusions and the plurality of second protrusion are alternately disposed in the first direction.

18. The thin film transistor substrate of claim 17,
wherein the current flows from one of the plurality of first protrusions to two adjacent second protrusions of the plurality of second protrusions.

19. A display device comprising the thin film transistor substrate according to claim 1.
